(19) United States
(12) Patent Application Publication
(10) Pub. No.: US 2026/0136957 A1
(43) Pub. Date: May 14, 2026

(54) PACKAGE STRUCTURE AND METHOD FOR FORMING THE SAME

(71) Applicant: JCET Microelectronics (Jiangyin) Co., LTD., Jiangyin (CN)

(72) Inventors: Qingyun ZHOU, Jiangyin (CN); Haijie CHEN, Jiangyin (CN); Jiayi ZHANG, Jiangyin (CN); Binjie LIU, Jiangyin (CN)

(21) Appl. No.: 19/384,628

(22) Filed: Nov. 10, 2025

(30) Foreign Application Priority Data
Nov. 11, 2024 (CN) 202411600518.9

(51) Int. Cl. H01L 23/538; H01L 21/48

(52) U.S. Cl. CPC H10W 70/611; H10W 70/095; H10W 70/635; H10W 70/65

(57) ABSTRACT

A package structure and a method for forming the same are provided. The method for forming a package structure includes: forming a bridge chip component, arranging the bridge chip component on a top surface of a carrier board; molding to form a first molding layer; forming a chip package component on a top surface of the first molding layer and a top surface of the bridge chip component; removing the carrier board; and forming a bottom redistribution layer on a bottom surface of the first molding layer and a bottom surface of the bridge chip component. A thickness of the bottom redistribution layer located on the bottom surface of the bridge chip component is greater than that of the bottom redistribution layer located on the bottom surface of the first molding layer, and the bridge chip component is electrically connected to the bottom redistribution layer.

### CROSS-REFERENCE TO RELATED APPLICATIONS

This application claims the benefit of priority to Chinese Application No. 202411600518.9, filed November 11, 2024, which is incorporated herein by reference in its entirety.

### TECHNICAL FIELD

The present disclosure relates to the field of semiconductor package, and particularly relates to a package structure and a method for forming the same.

### BACKGROUND

Advanced package is a novel electronic package technology, which is intended to integrate a plurality of chips or other electronic components together, with higher integration level, smaller size, lower power consumption, and higher reliability through innovative technical approaches.

### SUMMARY

Embodiments of the present disclosure provide a method for forming a package structure, including: forming a bridge chip component, the bridge chip component including a bridge chip, a protective layer, and an adhesive layer, the bridge chip including a base body and a through-silicon-via running through the base body, and the protective layer is arranged on the bottom surface of the base body and exposing the bottom surface of the through-silicon-via, wherein the bottom surface of the through-silicon-via is made flushed with the bottom surface of the protective layer by the way of first depositing the protective layer and then thinning the through-silicon-via, and the adhesive layer covers the bottom surface of the protective layer and the bottom surface of the through-silicon-via; arranging the bridge chip component on the top surface of a carrier board, the adhesive layer being contacted with the top surface of the carrier board; molding to form a first molding layer, the first molding layer covering the side surface of the bridge chip component and the top surface of the carrier board; forming a chip package component on the top surface of the first molding layer and the top surface of the bridge chip component, the bridge chip component being electrically connected with the chip package component; removing the carrier board and the adhesive layer of the bridge chip component, wherein the bottom surface of the bridge chip component is higher than the bottom surface of the first molding layer; and forming a bottom redistribution layer on the bottom surface of the first molding layer and the bottom surface of the bridge chip component, wherein the thickness of the bottom redistribution layer located on the bottom surface of the bridge chip component is greater than the thickness of the bottom redistribution layer located on the bottom surface of the first molding layer, the bridge chip component being electrically connected with the bottom redistribution layer.

The present disclosure further provides a package structure including: a bridge chip component, the bridge chip component including a bridge chip and a protective layer, the bridge chip including a base body and a through-silicon-via running through the base body, and the protective layer is arranged on the bottom surface of the base body and exposes the bottom surface of the through-silicon-via, the bottom surface of the through-silicon-via being flush with the bottom surface of the protective layer; a first molding layer, the first molding layer covering the side surfaces of the bridge chip component, and the bottom surface of the bridge chip component is higher than the bottom surface of the first molding layer; a chip package component arranged on the top surface of the first molding layer and the top surface of the bridge chip component, the bridge chip component being electrically connected with the chip package component; and a bottom redistribution layer arranged on the bottom surface of the first molding layer and the bottom surface of the bridge chip component, wherein the thickness of the bottom redistribution layer located on the bottom surface of the bridge chip component is greater than the thickness of the bottom redistribution layer located on the bottom surface of the first molding layer, and the bridge chip component is electrically connected with the bottom redistribution layer.

### BRIEF DESCRIPTION OF THE DRAWINGS

In order to explain the technical solutions in the embodiments of the present disclosure, the accompanying drawings required for the description of the embodiments will be briefly introduced below. It is obvious that the accompanying drawings described below are only some embodiments of the present disclosure, and for those skilled in the art, other accompanying drawings can be obtained according to these accompanying drawings without inventive effort.

FIG. 1 is a schematic diagram of the steps of a method for forming a package structure provided by an embodiment of the present disclosure;

FIGS. 2 to 16 are process flow schematic diagrams of a method for forming a package structure provided by an embodiment of the present disclosure; and

FIG. 17 is a schematic diagram of the semiconductor structure in a method for forming a package structure provided by an embodiment of the present disclosure.

### DETAILED DESCRIPTION

The specific implementation of the package structure and the method for forming the same provided by the present disclosure will be described in detail below with reference to the accompanying drawings.

In Wafer Level Package (WLP), most of its package processes are performed on the wafer, and the demand for wafer level package is not only subject to requirements for smaller package dimensions and height but also needs to meet the requirements of simplifying the supply chain, reducing overall costs, and improving overall performance.

Fan-out wafer level package can be categorized into Die First and Die Last processes based on process flow; Die First process simply means the chip is placed first, and then a wiring (e.g., a redistribution layer, RDL) is formed, and Die Last means a wiring is formed first, then the chip is placed onto the units that pass the test. In advanced package structure using Die Last, a bridge chip (e.g., a Si Bridge Die) needs to be embedded in the wiring interposer, and this bridge chip is a structure having TSV and DTC functionality. However, the reliability of this advanced package structure requires improvement.

Therefore, how to improve the reliability of package structures embedded in bridge dies has become a key focus of current research.

The technical problem to be solved by the present disclosure is to provide a package structure and a method for forming the same, which can improve the reliability of the package structure.

In the package structure and the method for forming the same provided by the embodiments of the present disclosure, a bridge chip component is first formed, wherein the through-silicon-vias of the bridge chip are exposed by the way of first depositing a protective layer and then thinning the through-silicon-via, so that the protective layer can protect the base body during the thinning process, which may avoid metal ions (e.g., copper ions) generated by thinning the through-silicon-via migrating and diffusing into the base body; meanwhile, when molding the bridge chip component, the bottom surface of the bridge chip component has an adhesive layer, and the adhesive layer is removed after molding, such that the bottom surface of the bridge chip component is higher than the bottom surface of the first molding layer, so that after a bottom redistribution layer is formed on the bottom surface of the first molding layer and the bottom surface of the bridge chip component, the thickness of the bottom redistribution layer located on the bottom surface of the bridge chip component is greater than the thickness of the bottom redistribution layer located on the bottom surface of the first molding layer, i.e., the bottom of the bridge chip component has a thicker dielectric layer.

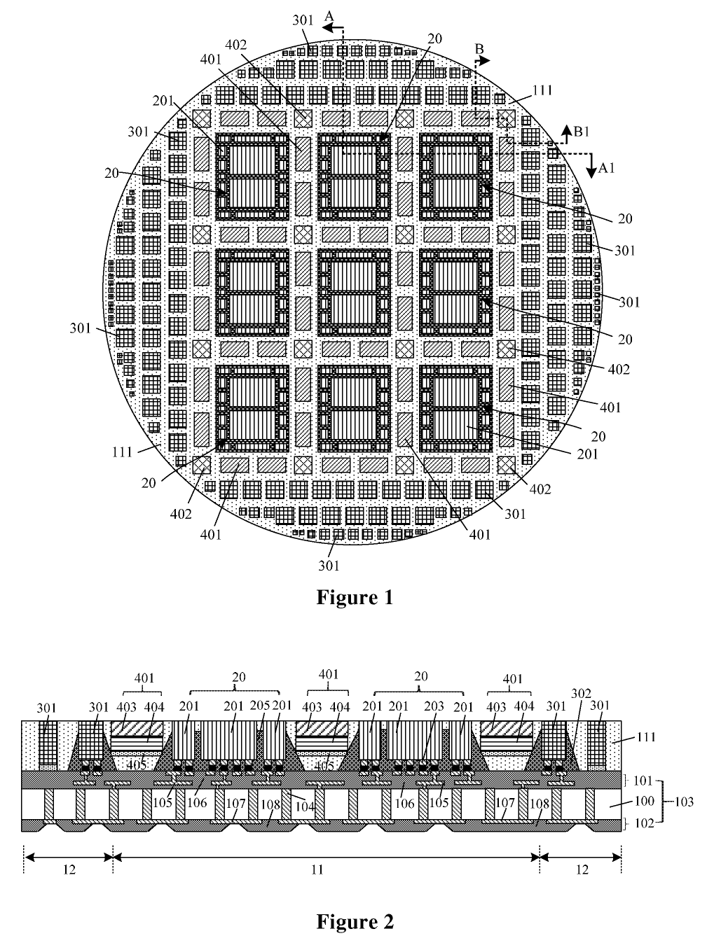

FIG. 1 is a schematic diagram of the steps of a method for forming a package structure provided by an embodiment of the present disclosure, referring to FIG. 1, the forming method includes: step S10, forming a bridge chip component, the bridge chip component including a bridge chip, a protective layer, and an adhesive layer, the bridge chip including a base body and a through-silicon-via running through the base body, and the protective layer is arranged on the bottom surface of the base body and exposing the bottom surface of the through-silicon-via, wherein the bottom surface of the through-silicon-via is made flushed with the bottom surface of the protective layer by the way of first depositing the protective layer and then thinning the through-silicon-via, and the adhesive layer covers the bottom surface of the protective layer and the bottom surface of the through-silicon-via; step S11, arranging the bridge chip component on the top surface of a carrier board, the adhesive layer being contacted with the top surface of the carrier board; step S12, molding to form a first molding layer, the first molding layer covering the side surface of the bridge chip component and the top surface of the carrier board; step S13, forming a chip package component on the top surface of the first molding layer and the top surface of the bridge chip component, the bridge chip component being electrically connected with the chip package component; step S14, removing the carrier board and the adhesive layer of the bridge chip component, wherein the bottom surface of the bridge chip component is higher than the bottom surface of the first molding layer; and step S15, forming a bottom redistribution layer on the bottom surface of the first molding layer and the bottom surface of the bridge chip component, wherein the thickness of the bottom redistribution layer located on the bottom surface of the bridge chip component is greater than the thickness of the bottom redistribution layer located on the bottom surface of the first molding layer, the bridge chip component being electrically connected with the bottom redistribution layer.

In the package structure and the method for forming the same provided by the embodiments of the present disclosure, a bridge chip component is first formed, wherein the through-silicon-vias of the bridge chip are exposed by the way of first depositing a protective layer and then thinning the through-silicon-via, so that the protective layer can protect the base body during the thinning process, which may avoid metal ions (e.g., copper ions) generated by thinning the through-silicon-via migrating and diffusing into the base body, thereby avoiding reliability failures in the package structure caused by metal ion migration and diffusion; meanwhile, when molding the bridge chip component, the bottom surface of the bridge chip component has an adhesive layer, and the adhesive layer is removed after molding, such that the bottom surface of the bridge chip component is higher than the bottom surface of the first molding layer, so that after a bottom redistribution layer is formed on the bottom surface of the first molding layer and the bottom surface of the bridge chip component, the thickness of the bottom redistribution layer located on the bottom surface of the bridge chip component is greater than the thickness of the bottom redistribution layer located on the bottom surface of the first molding layer, i.e., the bottom of the bridge chip component has a thicker dielectric layer, ensuring the connection strength of each connection point of the bridge chip component and providing higher stress buffering for the bridge chip, thereby improving the reliability of the package structure.

FIGS. 2 to 16 are process flow schematic diagrams of a method for forming a package structure provided by an embodiment of the present disclosure.

Referring to FIGS. 1 and 10, at step S10, a bridge chip component 100 is formed, the bridge chip component 100 includes: a bridge chip 110, a protective layer 120, and an adhesive layer 140, and the bridge chip 110 includes a base body 111 and a through-silicon-via 112 running through the base body 111, and the protective layer 120 is arranged on the bottom surface of the base body 111 and exposing the bottom surface of the through-silicon-via 112, wherein the bottom surface of the through-silicon-via 112 is made flushed with the bottom surface of the protective layer 120 by the way of first depositing the protective layer 120 and then thinning the through-silicon-via 112, and the adhesive layer 140 covers the bottom surface of the protective layer 120 and the bottom surface of the through-silicon-via 112.

In the bridge chip component 100 provided by the embodiment of the present disclosure, the bottom surface of the through-silicon-via 112 is flush with the bottom surface of the protective layer 120; when manufacturing the bridge chip component 100, the protective layer 120 is first deposited, and then the bottom surface of the through-silicon-via 112 is ground; during the grinding process, the protective layer 120 can protect the base body 111, which can avoid the migration and diffusion of metal ions (e.g., copper ions) generated by grinding the through-silicon-via 112 into the base body 111, thereby avoiding the reliability failure problem of the package structure caused by the migration and diffusion of metal ions.

In one embodiment, the base body 111 is a silicon base body, the through-silicon-via 112 is a copper pillar, and the protective layer 120 is a single-layer or composite-layer structure, and its materials include but are not limited to silicon nitride, silicon dioxide, or nitride-silicon dioxide. In one embodiment, a passivation layer 113 is further arranged on the side surface of the through-silicon-via 112, the passivation layer 113 is used to isolate the through-silicon-via 112 from the base body 111 to prevent diffusion of metal ions from the through-silicon-via into the base body 111.

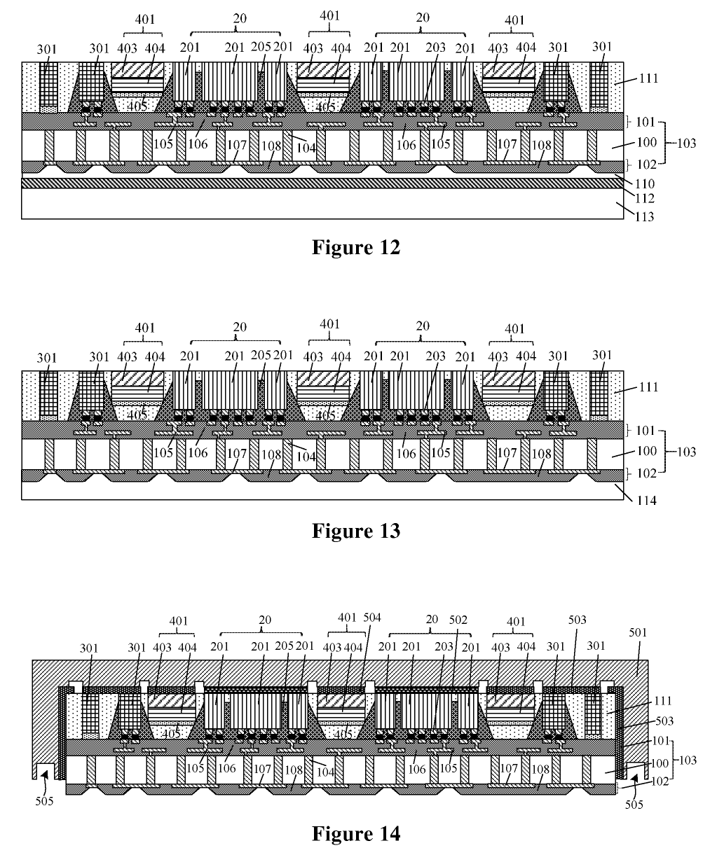

In one embodiment, the bridge chip component 100 further includes a bottom pad 130, the bottom pad 130 being arranged at the bottom surface of the through-silicon-via 112 and electrically connected with the through-silicon-via 112. In one embodiment, the bottom pad 130 is a micro pad (μPad). The bottom pad 130 is arranged at the bottom surface of the through-silicon-via 112, such that the thickness of the first molding layer 401 (referring to FIG. 12) covering the bridge chip component 100 in the package structure using the bridge chip component 100 can be reduced, thereby reducing the warping of this part of the structure, which is more conducive to production and yield. In the present embodiment, the cross-sectional area of the bottom pad 130 is larger than the cross-sectional area of the through-silicon-via 112 to ensure that the through-silicon-via 112 can fully contact the bottom pad 130, which reduces contact resistance, thereby reducing the delay of electrical signals.

The present disclosure further provides a method for forming a bridge chip component 100, in some embodiments, the step of forming a bridge chip component 100 includes:

Referring to FIG. 2, a device wafer is provided, the device wafer including a bridge chip 110, and the bridge chip 110 includes an initial base body 300, an initial through-silicon-via 310 extending from the top surface of the initial base body 300 toward the interior of the initial base body 300, and the side surface and bottom surface of the initial through-silicon-via 310 is covered with a passivation layer 113. The passivation layer 113 includes, but is not limited to, silicon oxide, silicon nitride, and their combinations.

In some embodiments, the bridge chip 110 further includes a deep trench capacitor (DTC) 180, and the deep trench capacitor 180 is arranged within the initial base body 300. In some embodiments, the deep trench capacitor 180 extends from the top surface of the initial base body 300 toward the interior of the initial base body 300. In one embodiment, the device wafer further includes an internal redistribution layer 160 and a conductive pillar 170, and the internal redistribution layer 160 is arranged on the top surface of the initial base body 300, and the conductive pillar 170 is arranged on the top surface of the internal redistribution layer 160, and the deep trench capacitor 180 is electrically connected with the internal redistribution layer 160.

In some embodiments, the step of providing a device wafer includes: providing an initial wafer, the initial wafer including an initial base body 300, an initial through-silicon-via 310 extending from the top surface of the initial base body 300 toward the interior of the initial base body 300, and a deep trench capacitor 180; forming an internal redistribution layer 160 and a conductive pillar 170 on the top surface of the initial base body 300, and the internal redistribution layer 160 is electrically connected with the top surface of the initial through-silicon-via 310, and the conductive pillar 170 is arranged on the top surface of the internal redistribution layer 160 and electrically connected with the internal redistribution layer 160. The internal redistribution layer 160 includes a dielectric layer and conductive lines within the dielectric layer, one side of the conductive lines being electrically connected with the top surface of the initial through-silicon-via 310, the other side being electrically connected with the conductive pillar 170. The initial through-silicon-via 310 includes, but is not limited to a copper pillar, the conductive pillar 170 includes, but is not limited to a copper pillar, the dielectric layer includes, but is not limited to a silicon dioxide layer or a silicon nitride layer, and etc. The initial base body 300 includes, but is not limited to a silicon base body. In some embodiments, the top surface of the initial through-silicon-via 310 and the deep trench capacitor 180 is flush with the top surface of the initial base body 300.

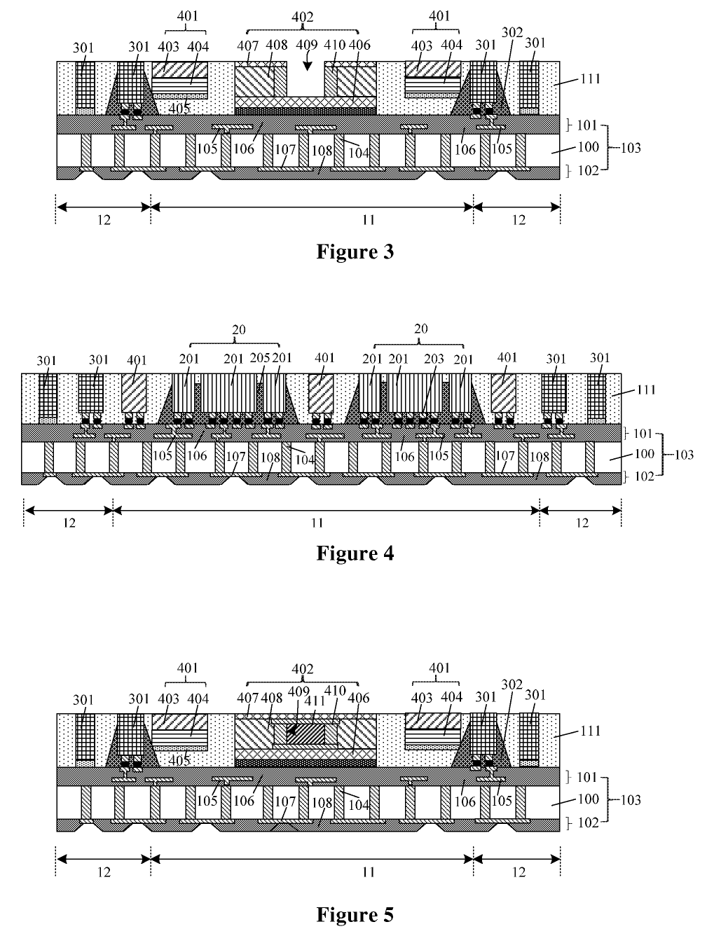

In some embodiments, in order for the device wafer to be supported in the subsequent step of processing the bottom surface of the device wafer (e.g., thinning the initial base body 300), after the step of providing the device wafer, it further includes: referring to FIG. 3, bonding the supporting substrate 320 with the front surface of the device wafer. The supporting substrate 320 includes, but is not limited to a glass substrate. Furthermore, the step of bonding the supporting substrate 320 with the front surface of the device wafer includes: bonding the supporting substrate 320 with the surface of the device wafer having the conductive pillar 170. In some embodiments, this step includes: forming a covering layer 330 on the front surface of the device wafer, the covering layer 330 covering the conductive pillar 170 and covering the surface of the internal redistribution layer 160; using the surface of the supporting substrate 320 and the surface of the covering layer 330 as bonding surfaces, bonding the supporting substrate 320 with the device wafer.

Referring to FIGS. 4 and 5, a part of the initial base body 300 is removed from the bottom surface of the initial base body 300 to form the base body 111, with the initial through-silicon-via 310 protruding from the bottom surface of the base body 111.

In some embodiments, this step may include the following two steps:

Referring to FIG. 4, a part of the initial base body 300 is removed from the bottom surface of the initial base body 300 to a predetermined distance from the passivation layer 113 on the bottom surface of the initial through-silicon-via 310. In some embodiments, the initial base body 300 is processed by the thinning and planarization process method from the bottom surface of the initial base body 300 to the vicinity of the initial through-silicon-via 310, and the initial through-silicon-via 310 is covered by the passivation layer 113, and the passivation layer 113 is covered by the initial base body 300, and the initial through-silicon-via 310 is still unexposed, which can avoid copper ion contamination of the base body 111 caused by the exposure of the initial through-silicon-via 310. During thinning, the supporting substrate 320 supports the device wafer. As shown in FIG. 4, at this step, the supporting substrate 320 is oriented downward, with the device wafer arranged above the supporting substrate 320.

Referring to FIG. 5, a part of the initial base body 300 is continuously removed from the bottom surface of the initial base body 300 to form the base body 111, with the initial through-silicon-via 310 protruding from the bottom surface of the base body 111. As shown in FIG. 5, during the execution of this step, the supporting substrate 320 is oriented downward, and the device wafer is arranged above the supporting substrate 320. In this step, the initial through-silicon-via 310 is not removed, such that the initial through-silicon-via 310 protrudes from the bottom surface of the base body 111. In some embodiments, a dry etching process may be used to remove a part of the initial base body 300, the dry etching material can etch the initial base body 300 without etching the passivation layer 113 on the surface of the initial through-silicon-via 310, thereby avoiding copper ion contaminating the base body 111 and subsequent process chambers.

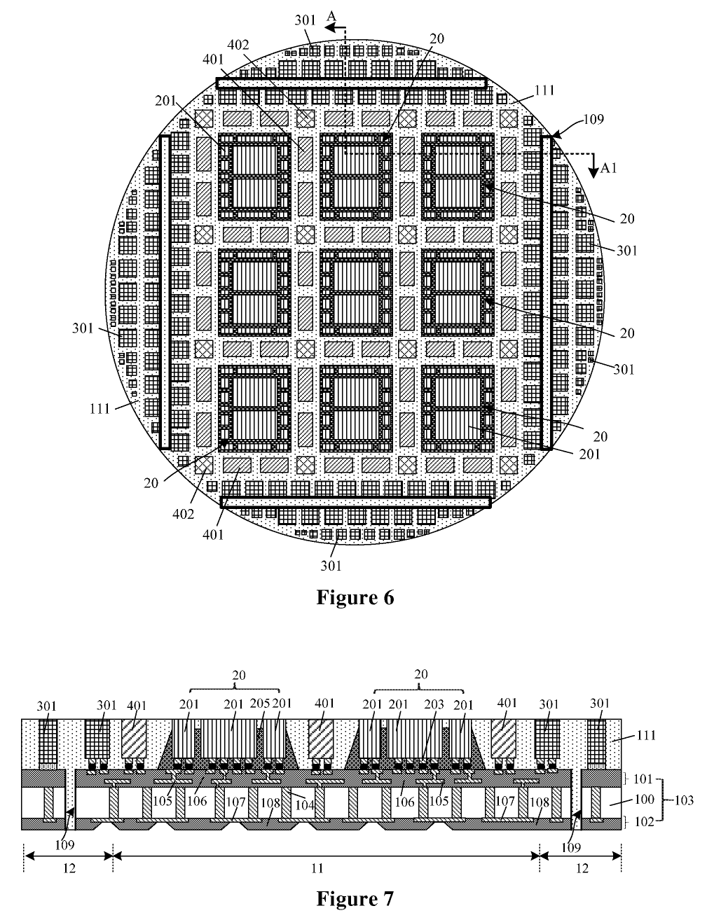

Referring to FIG. 6, a protective layer 120 is formed on the bottom surface of the base body 111, the protective layer 120 exposing the passivation layer 113 on the bottom surface of the initial through-silicon-via 310. In this step, the protective layer 120 may be formed using processes such as chemical vapor deposition (CVD), plasma-enhanced chemical vapor deposition (PECVD), or low-pressure chemical vapor deposition (LPCVD), the protective layer 120 being a single-layer structure or a composite-layer structure, its materials including but not limited to silicon nitride, silicon dioxide, or nitride-silicon dioxide.

Referring to FIG. 7, the passivation layer 113 and the initial through-silicon-via 310 are thinned from the bottom surface of the initial through-silicon-via 310 to form the through-silicon-via 112, thereby making the bottom surface of the through-silicon-via 112 flush with the bottom surface of the protective layer 120, with the side surface of the through-silicon-via 112 covered with the passivation layer 113. In this step, when thinning the initial through-silicon-via 310, the passivation layer 113 on the bottom surface of the initial through-silicon-via 310 is thinned first, when continuing to thin the initial through-silicon-via 310, the passivation layer 113 on the side surface of the initial through-silicon-via 310 is simultaneously removed. In this step, the initial through-silicon-via 310 may be ground using a chemical mechanical grinding process until the formed through-silicon-via 112 meets a predetermined height requirement. In some embodiments, the bottom surface of the protective layer 120 is simultaneously ground to provide a flat surface for subsequent processes. In this step, when grinding the initial through-silicon-via 310, the base body 111 surface is covered by the protective layer 120, and the metal ions generated during grinding cannot diffuse into the base body 111, thereby avoiding reliability failures of the package structure caused by the migration and diffusion of metal ions.

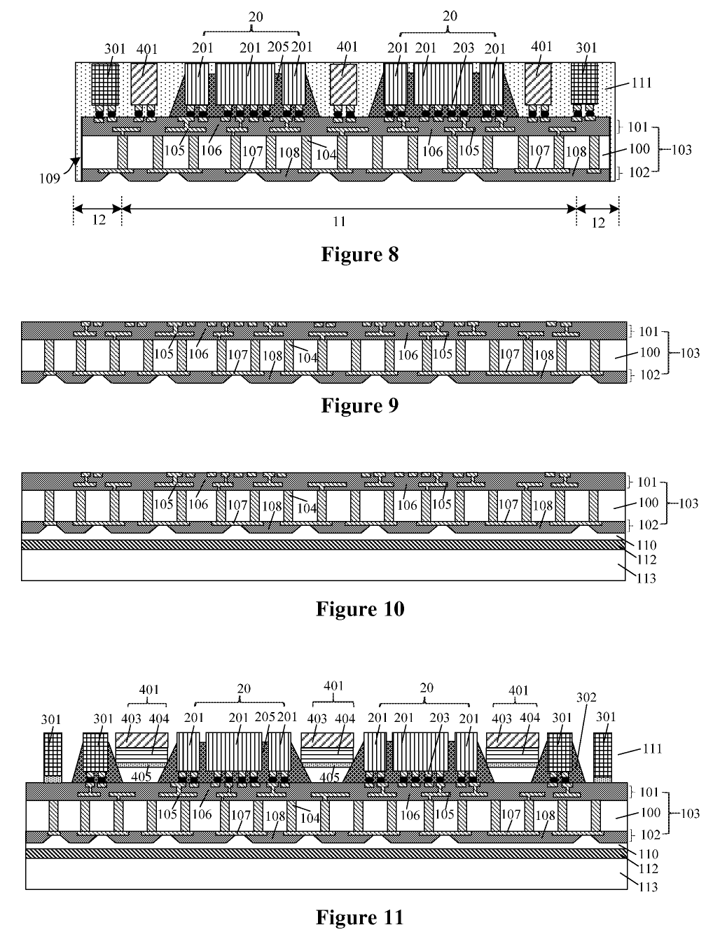

In some embodiments, after the step of thinning the passivation layer 113 and the initial through-silicon-via 310 from the bottom surface of the initial through-silicon-via 310 to form the through-silicon-via 112, it further includes: referring to FIG. 8, a bottom pad 130 is formed, and the bottom pad 130 is arranged at the bottom surface of the through-silicon-via 112 and electrically connected with the through-silicon-via 112. The bottom pad 130 serves as the structure for connecting the silicon via 112 to the outside. In one embodiment, the bottom pad 130 is a micro-pad (μPad). The bottom pad 130 may be formed through photolithography and electroplating processes.

In some embodiments, the step of forming the bottom pad 130 further includes: forming a seed layer 150 on the bottom surface of the protective layer 120 and the bottom surface of the through-silicon-via 112; and forming the bottom pad 130 on the seed layer 150 on the bottom surface of the through-silicon-via 112 using an electroplating process. The seed layer 150 may be a copper layer, a titanium layer, or a multi-layer metal layer. In one embodiment, as shown in FIG. 8, the forming method further includes: removing the seed layer 150 not covered by the bottom pad 130, and only retaining the seed layer 150 located in the area of the bottom pad 130. In other embodiments, referring to FIG. 17, the seed layer 150 may not be removed after forming the bottom pad 130, but rather the seed layer 150 is removed during subsequent process.

Referring to FIG. 9, an adhesive layer 140 is formed, the adhesive layer 140 covering the bottom surface of the protective layer 120 and the bottom surface of the bottom pad 130. In some embodiments, in this step, the adhesive layer 140 is formed on the bottom surface of the protective layer 120 and the bottom surface of the bottom pad 130. The bridge chip component 100 is secured on the wafer ring 350 by the adhesive layer 140. In some embodiments, the bottom surface of the device wafer is secured on the wafer ring 350 by the adhesive layer 140, with the supporting substrate 320 facing upward. The adhesive layer 140 is composed of a material with a certain viscosity, such as an acrylic resin series. In some embodiments, the adhesive layer 140 is a Die Attachment Film (DAF) with excellent thermal conductivity and adhesion. In some embodiments, as shown in FIG. 17, the seed layer 150 is not removed after forming the bottom pad 130, the adhesive layer 140 covering the bottom surface of the seed layer 150 and the bottom surface of the bottom pad 130.

In some embodiments, after the step of forming the adhesive layer 140, it further includes: referring to FIG. 10, debonding the supporting substrate 320 and dicing the device wafer to form the bridge chip component 100. In this step, after debonding the supporting substrate 320, the covering layer 330 on the front surface of the device wafer is also removed, with the conductive pillar 170 exposed. In some embodiments, an appropriate debonding process may be selected based on the characteristics of the temporary bonding adhesive, such as laser debonding or thermal debonding and etc. The device wafer is diced to form a plurality of independent bridge chip components 100.

The above is an embodiment of forming a bridge chip component 100.

Referring to FIGS. 1 and 11, at step S11, the bridge chip component 100 is arranged on the top surface of a carrier board 600, with the adhesive layer 140 contacting the top surface of the carrier board 600.

In some embodiments, the carrier board 600 is a glass base body with a temporary bonding layer 601 and a buffer metal layer 602 on its surface. The bridge chip component 100 is arranged on the buffer metal layer 602 by a chip mounting or a chip bonding (Die Attach, DA) process. In some embodiments, in this step, a metal pillar 402 is further arranged on the surface of the carrier board 600.

Referring to FIGS. 1 and 12, at step S12, molding is performed to form a first package layer 401, the first package layer 401 covering the side surface of the bridge chip component 100 and the top surface of the carrier board 600. In some embodiments, this step further includes: covering the bridge chip component 100, the metal pillar 402, and the surface of the buffer metal layer 602 covering the carrier board 600 using a molding compound; preliminarily thinning the molding compound to expose the metal pillar 402 and the conductive pillar 170 on the top surface of the bridge chip component 100; etching the metal pillar 402 and the conductive pillar 170 on the top surface of the bridge chip component 100 to a predetermined height; continuing to thin the molding compound to form the first molding layer 401, the top surface of the first molding layer 401 is flush with the top surfaces of the metal pillar 402 and the top surface of the conductive pillar 170, and the top surface of the metal pillar 402 and the top surface of the conductive pillar 170 are not covered by the first molding layer 401. By etching the metal pillar 402 and the conductive pillar 170 after preliminarily thinning the molding compound, it is able, on the one hand, to form a predetermined height, and, on the other hand, to remove the oxide layer on the surfaces of the metal pillar 402 and the conductive pillar 170, exposing the base body and reducing the contact resistance between the metal pillar 402 and conductive pillar 170 on the one hand, and other device layers (e.g., the top redistribution layer 430) on the other hand.

Referring to FIGS. 1 and 13, at step S13, a chip package component 400 is formed on the top surface of the first molding layer 401 and the top surface of the bridge chip component 100, the bridge chip component 100 being electrically connected with the chip package component 400.

In one embodiment, the chip package component 400 includes a top redistribution layer 430, a top pad 440, and a top device 450, the step of forming the chip package component 400 on the top surface of the first molding layer 401 and the top surface of the bridge chip component 100 includes:

Forming a top redistribution layer 430 on the top surface of the first molding layer 401 and the top surface of the bridge chip component 100. The top redistribution layer 430 includes a dielectric layer 431 and electroplated wires 432 within the dielectric layer 431, the electroplated wires 432 are electrically connected with conductive pillar 170 of the bridge chip component 100, wherein the electroplated wires 432 are formed by a electroplating process. In one embodiment, the top redistribution layer 430 may be formed by photolithography and electroplating processes, for example, the top redistribution layer 430 is formed by layering and stacking through processes such as resist coating, exposure, development, electroplating, and resist removal.

A top pad 440 is formed on the top surface of the top redistribution layer 430, and the top pad 440 is electrically connected with the top redistribution layer 430.

A top device 450 is arranged on the top redistribution layer 430, and the top device 450 is soldered with the top pad 440. In some embodiments, the top device 450 is flip-flop mounted on the top redistribution layer 430. The top device 450 is soldered with the top pad 440 through conductive bumps.

Molding the top device 450 to form a second package layer 470, the second package layer 470 covering the top device 450. In some embodiments, before molding the top device 450, it further includes forming a filler layer 460 by filling between the bottom of the top device 450 and the top redistribution layer 430, the second package layer 470 also covering the filler layer 460.

Referring to FIGS. 1 and 14, at step S14, the carrier board 600 and the adhesive layer 140 of the bridge chip component 100 are removed, wherein the bottom surface of the bridge chip component 100 is higher than the bottom surface of the first molding layer 401. The bottom surface of the first molding layer 401, the bottom surface of the metal pillar 402, and the bottom surface of the bridge chip 110 are also exposed.

In this step, an appropriate debonding process is selected based on the characteristics of the temporary bonding adhesive, such as laser debonding or thermal debonding, and etc. to remove the carrier board 600. After removing the carrier board 600, it further includes etching to remove the buffer metal layer 602 on the surface of the base body. In this step, an appropriate etching process is selected based on the material properties and molecular system of the adhesive layer 140 to remove the adhesive layer 140, exposing the bottom pad 130 on the back surface of the bridge chip 110.

In some embodiments, the bridge chip component 100 further includes a seed layer 150, the seed layer 150 covering the bottom surface of the protective layer 120 and the bottom surface of the through-silicon-via 112 of the bridge chip component 100, and the bottom pad 130 is arranged on the seed layer 150, the adhesive layer 140 also covering the bottom surface of the seed layer 150 (referring to FIG. 17), after the step of removing the adhesive layer 140, it further includes: removing the seed layer 150 outside the area of the bottom pad 130, so that it is able to completely remove residual adhesive layer 140, which improves the reliability of the package structure.

In some embodiments, after removing the carrier board 600, the adhesive layer 140, or the seed layer 150, it further includes a cleaning process to remove residual substances.

In some embodiments, in the step of removing the adhesive layer 140 and the seed layer 150, if a dry etching process is used, it may cause the bottom surface of the first molding layer 401 to be too rough, then the forming method further includes polishing the bottom surface of the first molding layer 401 to form a surface with a roughness that meets the requirements.

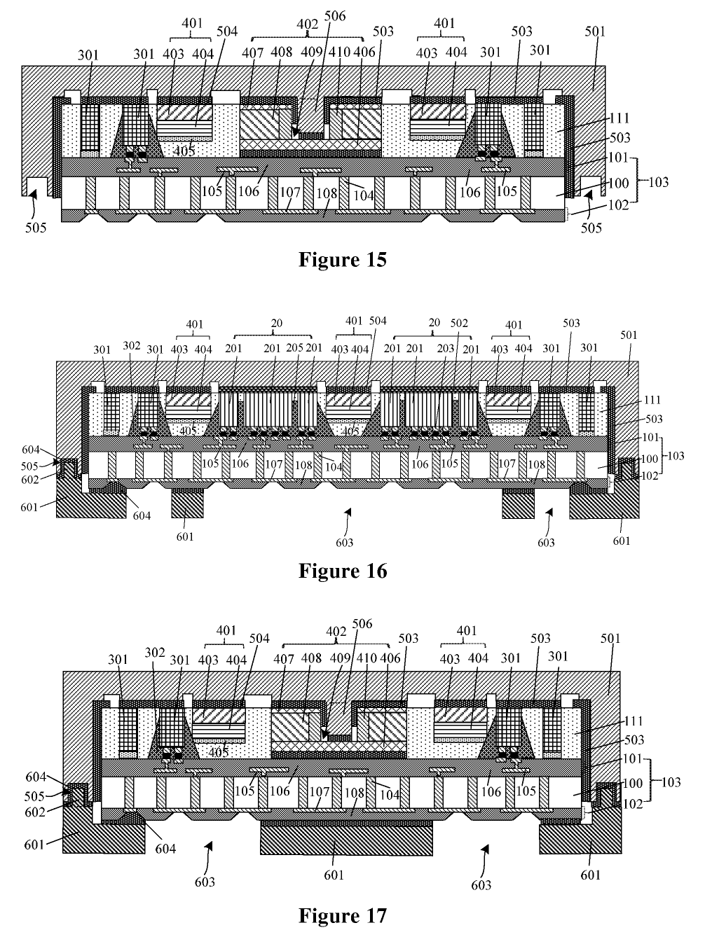

Referring to FIGS. 1 and 15, at step S15, a bottom redistribution layer 410 is formed on the bottom surface of the first molding layer 401 and the bottom surface of the bridge chip component 100, wherein the thickness of the bottom redistribution layer 410 located on the bottom surface of the bridge chip component 100 is greater than the thickness of the bottom redistribution layer 410 located on the bottom surface of the first molding layer 401, and the bridge chip component 100 is electrically connected with the bottom redistribution layer 410. Wherein the through-silicon-via 112 of the bridge chip 110 is electrically connected with the bottom redistribution layer 410.

In this step, the thickness of the bottom redistribution layer 410 located on the bottom surface of the bridge chip component 100 is greater than the thickness of the bottom redistribution layer 410 located on the bottom surface of the first molding layer 401, the bottom of the bridge chip component 100 has a thicker dielectric layer, such that the connection strength of each connection point of the bridge chip component 100 is ensured and higher stress buffering is provided for the bridge chip 110, improving the reliability of the package structure.

In some embodiments, the step of forming the bottom redistribution layer 410 on the bottom surface of the first molding layer 401 and the bottom surface of the bridge chip component 100 further includes:

Forming a dielectric layer 411 on the bottom surface of the first molding layer 401 and the bottom surface of the bridge chip component 100.

Forming, on the dielectric layer 411, a through-via exposing the bottom pads 130 on the bottom surface of the bridge chip 110 through a single exposure or dual exposure process. In some embodiments, if the distance between the surface of the bottom pads 130 and the bottom surface of the first molding layer 401 is too great, using a single exposure process may fail to fully expose the bottom pad 130, then a double exposure process may be used to form, on the dielectric layer 411, a through-via exposing the bottom pad 130 of the bottom surface of the bridge chip 110, such that the through-via can fully expose the bottom pad 130. In some embodiments, when the bottom pad 130 is not arranged on the bottom surface of the through-silicon-via 112, the determination of using a single exposure or a double exposure process to form a through-hole exposing the bottom surface of the through-silicon-via 112 on the dielectric layer 411 is based on the distance from the bottom surface of the through-silicon-via 112 to the bottom surface of the first molding layer 401.

An electroplated bump 412 is formed within the through-via by sputtering and/or electroplating, the electroplated bump 412 being in contact connection with the bottom pad 130 of the bridge chip 110. In this step, the electroplated bump 412 is formed using sputtering and electroplating, without the need for tin (Sn) soldering, removing aging issues of the tin soldering during process machining, and there are no issues of voids or cracks at the soldering points, improving the reliability of the package structure; moreover, the combination of sputtering and electroplating can balance efficiency and costs.

In some embodiments, after forming the bottom redistribution layer 410 on the bottom surface of the first molding layer 401 and the bottom surface of the bridge chip component 100, it further includes: referring to FIG. 16, forming a conductive connection structure 630 on the bottom surface of the bottom redistribution layer 410. In some embodiments, the conductive connection structure 630 is formed on the bottom surface of the bottom redistribution layer 410. The conductive connection structure 630 is electrically connected with the bottom redistribution layer 410. In some embodiments, the conductive connection structure 630 includes, but is not limited to controllable collapse chip connection bumps (C4).

In some embodiments, after or before forming the conductive connection structure 630, the second molding layer 470 is thinned to expose the top surface of the top device 450, which is beneficial for device heat dissipation. In some embodiments, after forming the conductive connection structure 630, dicing is performed to form a plurality of independent package structures, each of the package structure may include a plurality of bridge chip components 100 and a plurality of top devices 450.

In the package structure and the method for forming the same provided by the embodiments of the present disclosure, a bridge chip component is first formed, wherein the through-silicon-via of the bridge chip are exposed by the way of first depositing a protective layer and then thinning the through-silicon-via, so that the protective layer can protect the base body during the thinning process, which may avoid metal ions (e.g., copper ions) generated by thinning the through-silicon-via migrating and diffusing into the base body, thereby avoiding reliability failures in the package structure caused by metal ion migration and diffusion; meanwhile, when molding the bridge chip component, the bottom surface of the bridge chip component has an adhesive layer, and the adhesive layer is removed after molding, such that the bottom surface of the bridge chip component is higher than the bottom surface of the first molding layer, so that after a bottom redistribution layer is formed on the bottom surface of the first molding layer and the bottom surface of the bridge chip component, the thickness of the bottom redistribution layer located on the bottom surface of the bridge chip component is greater than the thickness of the bottom redistribution layer located on the bottom surface of the first molding layer, i.e., the bottom of the bridge chip component has a thicker dielectric layer, ensuring the connection strength of each connection point of the bridge chip component and providing higher stress buffering for the bridge chip, thereby improving the reliability of the package structure.

Based on the same inventive concept, the embodiments of the present disclosure further provide a package structure formed using the aforementioned forming method. As shown in FIGS. 2 to 16, the package structure includes: a bridge chip component 100, and the bridge chip component 100 includes a bridge chip 110 and a protective layer 120, and the bridge chip 110 includes a base body 111 and a through-silicon-via 112 running through the base body 111; the protective layer 120 is arranged on the bottom surface of the base body 111 and exposing the bottom surface of the through-silicon-via 112, wherein the bottom surface of the through-silicon-via 112 is flush with the bottom surface of the protective layer 120; a first molding layer 401, the first molding layer 401 covering the side surface of the bridge chip component 100, and the bottom surface of the bridge chip component 100 is higher than the bottom surface of the first molding layer 401; a chip package component 400 arranged on the top surface of the first molding layer 401 and the top surface of the bridge chip component 100, the bridge chip component 100 being electrically connected with the chip package component 400; and a bottom redistribution layer 410 arranged on the bottom surface of the first molding layer 401 and the bottom surface of the bridge chip component 100, wherein the thickness of the bottom redistribution layer 410 located on the bottom surface of the bridge chip component 100 is greater than the thickness of the bottom redistribution layer 410 located on the bottom surface of the first molding layer 401, the bridge chip component 100 being electrically connected with the bottom redistribution layer 410.

In the package structure provided by the embodiments of the present disclosure, the bottom surface of the through-silicon-via 112 is flush with the bottom surface of the protective layer 120, wherein when manufacturing the bridge chip component 100, the protective layer 120 is first formed, and then the bottom surface of the through-silicon-via 112 is ground, during the grinding, the protective layer 120 can protect the base body 111, and avoid the migration and diffusion of metal ions (e.g., copper ions) generated by grinding the through-silicon-via 112 into the base body 111, thereby avoiding the reliability failure issues of the package structure caused by the migration and diffusion of metal ions. Moreover, the thickness of the bottom redistribution layer located on the bottom surface of the bridge chip component is greater than the thickness of the bottom redistribution layer located on the bottom surface of the first molding layer, i.e., the bottom of the bridge chip component has a thicker dielectric layer, such that the connection strength of each contact point of the bridge chip component is ensured, and higher stress buffering is provided for the bridge chip, improving the reliability of the package structure.

In one embodiment, the base body 111 is a silicon base body, and the through-silicon-via 112 is a copper pillar, and the protective layer 120 is a single-layer structure or a composite-layer structure, and its materials include but are not limited to silicon nitride, silicon dioxide, or nitride-silicon dioxide.

In one embodiment, the bridge chip component 100 further includes a bottom pad 130, and the bottom pad 130 is arranged at the bottom surface of the through-silicon-via 112 and is electrically connected with the through-silicon-via 112, the bottom redistribution layer 410 being electrically connected with the bottom pad 130, i.e., the through-silicon-via 112 being electrically connected with the bottom redistribution layer 410 through the bottom pad 130. In one embodiment, the bottom pad 130 is a micro solder pad (μPad). The bottom pad 130 is arranged at the bottom surface of the through-silicon-via 112, such that it can reduce the thickness of the first molding layer 401 covering the bridge chip component 100 in the package structure using the bridge chip component 100, thereby reducing the warping of this part of structure, which is more conducive to production and yield. In the present embodiment, the cross-sectional area of the bottom pad 130 is larger than the cross-sectional area of the through-silicon-via 112 to ensure that the through-silicon-via 112 can fully contact the bottom pad 130, which reduces contact resistance, thereby making the delay of electrical signals smaller.

In one embodiment, the bridge chip component 100 further includes a seed layer 150 arranged between the bottom pad 130 and the bottom surface of the through-silicon-via 112, and the bottom pad 130 is formed by electroplating at the surface of the seed layer 150. The seed layer 150 may is a copper layer, a titanium layer, or a multi-layer metal layer. As shown in FIG. 8, the seed layer 150 is located in the area corresponding to the bottom pad 130, with the bottom pad 130 arranged on the seed layer 150, i.e., the seed layer 150 is not arranged in other areas of the protective layer 120.

In one embodiment, a passivation layer 113 is further arranged on the side surface of the through-silicon-via 112, and the passivation layer 113 is used to isolate the through-silicon-via 112 from the base body 111 to avoid metal ions in the through-silicon-via diffusing into the base body 111.

In one embodiment, the bridge chip component 100 further includes an internal redistribution layer 160 and a conductive pillar 170. The internal redistribution layer 160 is arranged on the top surface of the base body 111 and is electrically connected with the top surface of the through-silicon-via 112. The conductive pillar 170 is arranged on the top surface of the internal redistribution layer 160 and is electrically connected with the internal redistribution layer 160. The chip package component 400 is electrically connected with the conductive pillar 170. The internal redistribution layer 160 includes a dielectric layer and conductive lines within the dielectric layer, one side of the conductive lines is electrically connected with the top surface of the through-silicon-via 112, and the other side of the conductive lines is electrically connected with the conductive pillar 170. The conductive pillar 170 includes, but is not limited to a copper pillar, the dielectric layer may be a silicon dioxide layer or a silicon nitride layer, and etc.

In one embodiment, the bridge chip 110 further includes a deep trench capacitor (DTC) 180, and the deep trench capacitor 180 is arranged within the base body 111. In some embodiments, the deep trench capacitor 180 extends from the top surface of the base body 111 toward the interior of the base body 111, and the deep trench capacitor 180 is electrically connected with the internal redistribution layer 160.

In one embodiment, the bottom surface of the through-silicon-via 112 is electrically connected with other structural layers (e.g., the bottom redistribution layer 410) through the bottom pad 130, which reduces the thickness of the first molding layer 401 covering the bridge chip component 100, thereby reducing warping of this part of structure, which is more conducive to production and yield.

In some embodiments, the first molding layer 401 covers the side surface of the bridge chip component 100, the surface of the internal redistribution layer 160, and the side surface of the conductive pillar 170.

In some embodiments, the package structure further includes a metal pillar 402, the metal pillar 402 runs through the first molding layer 401, and the bottom surface of the metal pillar 402 is flush with the bottom surface of the first molding layer 401. In one embodiment, the top surface of the metal pillar 402 is flush with the top surface of the conductive pillar 170. The metal pillar 402 and the conductive pillar 170 may be of the same material, for example, both are of copper. The package structure may include a plurality of bridge chip components 100 and a plurality of metal pillars 402, the metal pillars 402 are distributed around the periphery of the bridge chip components 100 and between the two adjacent bridge chip components 100.

In some embodiments, the bottom redistribution layer 410 also covers the bottom surface of the metal pillar 402, the metal pillar 402 being electrically connected with the bottom redistribution layer 410, and the thickness of the bottom redistribution layer 410 located in the area of the metal pillar 402 is the same as the thickness of the bottom redistribution layer 410 located in the area of the first molding layer 401.

In some embodiments, the bottom redistribution layer 410 includes a dielectric layer 411 and an electroplated bump 412 within the dielectric layer 411, the electroplated bump 412 being in contact connection with the bottom pad 130 of the bridge chip 110. The material of the dielectric layer 411 may be a polymeric material such as polystyrene butadiene oxide (PBO) or polyimide (PI) and etc. to further reduce stress. The electroplated bump 412 refers to a bump formed through an electroplating process. In one embodiment, the electroplated bump 412 is formed on the surface of the bottom pad 130 through an electroplating process, without the need for tin (Sn) soldering, which removes aging issues of the tin soldering during process machining, and there are no issues of voids or cracks at the soldering points, improving the reliability of the package structure.

In some embodiments, the chip package component 400 includes a top redistribution layer 430, a top pad 440, a top device 450, and a second molding layer 470.

The top redistribution layer 430 is arranged on the top surface of the first molding layer 401 and the top surface of the bridge chip component 100, and the top redistribution layer 430 includes a dielectric layer 431 and electroplated wires 432 within the dielectric layer 431, and the electroplated wires 432 are electrically connected with the conductive pillar 170 of the bridge chip component 100. In some embodiments, the top surface of the metal pillar 402 is in contact connection with the electroplated wires 432. In some embodiments, the material of the dielectric layer 431 may be a polymeric material such as polystyrene butadiene oxide (PBO) or polyimide (PI) and etc. The electroplated wire 432 refers to a wire formed through an electroplating process. In one embodiment, the electroplated wire 432 is formed through electroplating process on the surface of the through-silicon-via 112 and the metal pillar 402, without the need for tin (Sn) soldering, which removes aging issues of the tin soldering during process machining, and there are no issues of voids or cracks at the soldering points, improving the reliability of the package structure.

The top pad 440 is arranged on the top surface of the top redistribution layer 430 and is electrically connected with the top redistribution layer 430. In one embodiment, the top pad 440 is a micro-pad (μPad).

The top device 450 is arranged on the top redistribution layer 430 and soldered with the top pad 440. The top device 450 may be flip-flop mounted on the top redistribution layer 430 and soldered with the top pad 440. The top device 450 may be an SOC device, and etc.

The second molding layer 470 covers the top device 450. In some embodiments, the package structure further includes a filler layer 460 filled between the bottom of the top device 450 and the top redistribution layer 430, the filler layer 460 being used to protect the conductive structure of the top device 450 and the top pad 440. The second molding layer 470 covers the top device 450, the surface of the top redistribution layer 430, and the surface of the filler layer 460.

In some embodiments, the package structure further includes a conductive connection structure 630, and the conductive connection structure 630 is arranged on the bottom surface of the bottom redistribution layer 410. In some embodiments, the conductive connection structure 630 includes, but is not limited to controllable collapse chip connection bump (C4).

The package structure provided by the embodiments of the present disclosure avoid the migration and diffusion of metal ions (e.g., copper ions) generated by grinding the through-silicon-via 112 into the base body 111 by arranging the protective layer 120, which improves the reliability of the packaging structure. In the package structure provided by the embodiments of the present disclosure, the bridge chip uses a front-fit manner, and the thickness of the chip is thinner, the thickness of the first molding layer is thinner, such that the lengths of the through-silicon-via and the metal pillar are shorter, the delay of electrical signal is less, and there are less restrictions on the size and aspect ratio of the bridge chip. Meanwhile, the thickness of the bottom redistribution layer located on the bottom surface of the bridge chip component is greater than the thickness of the bottom redistribution layer located on the bottom surface of the first molding layer, i.e., the bottom of the bridge chip component has a thicker dielectric layer, thus ensuring the connection strength of each connection point of the bridge chip component and providing higher stress buffering for the bridge chip, thereby improving the reliability of the package structure.

It should be noted that the terms “include” and “have” and their variations referred to in the document of the present disclosure are intended to cover non-exclusive inclusions. The terms such as “first,” “second,” etc., are used to distinguish similar objects and are not necessarily used to describe a specific order or sequence, and it is appreciated that unless otherwise indicated in the context clearly, the data used in this way can be interchanged in appropriate circumstances. The term “one or more” is at least partially dependent on the context and may be used to describe features, structures, or characteristics in a singular sense or in a plural sense. The term “based on” may be understood as not necessarily intended to express a set of exclusive factors, but may alternatively, be also at least partially dependent on the context, permit the existence of other factors that may not be explicitly described. In addition, the embodiments of the present disclosure and features in the embodiments may be combined with each other without conflict. Additionally, in the above explanation, descriptions of well-known components and technologies have been omitted to avoid unnecessary confusion of the concepts of the present disclosure. In the above embodiments, each embodiment focuses on illustrating differences from other embodiments, and the same/similar parts between the embodiments can be referred to each other.

The above is only the embodiments of the present disclosure, it should be noted that those skilled in the art may also make several improvements and refinements without departing from the principles of the present disclosure, and these improvements and refinements should also be considered as the protection scope of the present disclosure.

What is claimed is:

1. A method for forming a package structure, comprising:
forming a bridge chip component, wherein:
the bridge chip component comprises a bridge chip; a protective layer; and an adhesive layer;
the bridge chip comprises a base body and a through-silicon-via extending through the base body;
the protective layer is arranged on a bottom surface of the base body exposing a bottom surface of the through-silicon-via, wherein the bottom surface of the through-silicon-via is flush with a bottom surface of the protective layer by a way of first depositing the protective layer and then thinning the through-silicon-via; and
the adhesive layer covers the bottom surface of the protective layer and the bottom surface of the through-silicon-via;
arranging the bridge chip component on a top surface of a carrier board, wherein the adhesive layer is in contact with the top surface of the carrier board;
molding to form a first molding layer, wherein the first molding layer covers a side surface of the bridge chip component and the top surface of the carrier board;
forming a chip package component on a top surface of the first molding layer and a top surface of the bridge chip component, wherein the bridge chip component is electrically connected to the chip package component;
removing the carrier board and the adhesive layer of the bridge chip component, wherein a bottom surface of the bridge chip component is higher than a bottom surface of the first molding layer; and
forming a bottom redistribution layer on the bottom surface of the first molding layer and the bottom surface of the bridge chip component, wherein a thickness of the bottom redistribution layer located on the bottom surface of the bridge chip component is greater than that of the bottom redistribution layer located on the bottom surface of the first molding layer, and the bridge chip component is electrically connected to the bottom redistribution layer.

2. The method for forming a package structure according to claim 1, wherein forming the bridge chip component further comprises:
providing a device wafer, wherein:
the device wafer comprises a bridge chip;
the bridge chip comprises an initial base body, and an initial through-silicon-via extending from a top surface of the initial base body toward an interior of the initial base body; and
a side surface and a bottom surface of the initial through-silicon-via are covered with a passivation layer;
removing a part of the initial base body from the bottom surface of the initial base body to form the base body, the initial through-silicon-via protruding from the bottom surface of the base body;
forming the protective layer on the bottom surface of the base body, wherein the protective layer exposes to the passivation layer on the bottom surface of the initial through-silicon-via;
thinning the passivation layer and the initial through-silicon-via from the bottom surface of the initial through-silicon-via to form the through-silicon-via, so that the bottom surface of the through-silicon-via is flush with the bottom surface of the protective layer, wherein a side surface of the through-silicon-via is covered with the passivation layer; and
forming the adhesive layer.

3. The method for forming a package structure according to claim 2, wherein after thinning the passivation layer and the initial through-silicon-via from the bottom surface of the initial through-silicon-via to form the through-silicon-via, the method further comprises:
forming a bottom pad, wherein the bottom pad is arranged on the bottom surface of the through-silicon-via and is electrically connected to the through-silicon-via;
when forming the adhesive layer, the adhesive layer covers a surface of the bottom pad and the bottom surface of the protective layer; and
when forming a bottom redistribution layer on the bottom surface of the first molding layer and the bottom surface of the bridge chip component, the through-silicon-via is electrically connected to the bottom redistribution layer through the bottom pad.

4. The method for forming a package structure according to claim 3, wherein forming the bottom pad further comprises:
forming a seed layer on the bottom surface of the protective layer and the bottom surface of the through-silicon-via; and
forming the bottom pad on the seed layer at the bottom surface of the through-silicon-via using an electroplating process.

5. The method for forming a package structure according to claim 4, wherein after forming the bottom pad, the method further comprises:
removing a portion of the seed layer that is not covered by the bottom pad.

6. The method for forming a package structure according to claim 4, wherein when forming the adhesive layer, the adhesive layer covers the surface of the bottom pad and a bottom surface of the seed layer; and
wherein after removing the adhesive layer, the method further comprises: removing the seed layer.

7. The method for forming a package structure according to claim 2, wherein after providing a device wafer, the method further comprises: bonding a supporting substrate to a front surface of the device wafer; and
wherein after forming the adhesive layer, the method further comprises: debonding the supporting substrate and dicing the device wafer to form the bridge chip component.

8. The method for forming a package structure according to claim 7, wherein providing the device wafer further comprises:
forming an internal redistribution layer and a conductive pillar on the top surface of the initial base body, wherein the internal redistribution layer is electrically connected to a top surface of the initial through-silicon-via, and the conductive pillar is arranged on a top surface of the internal redistribution layer and is electrically connected to the internal redistribution layer; and
wherein bonding the supporting substrate to the front surface of the device wafer further comprises: bonding the supporting substrate to a surface of the device wafer having the conductive pillar.

9. The method for forming a package structure according to claim 1, wherein arranging the bridge chip component on a top surface of a carrier board further comprises:
arranging a metal pillar on the top surface of the carrier board; and
wherein when molding to form the first molding layer, the first molding layer covers a side surface of the metal pillar.

10. The method for forming a package structure according to claim 1, wherein forming a chip package component on a top surface of the first molding layer and a top surface of the bridge chip component further comprises:
forming a top redistribution layer on the top surface of the first molding layer and the top surface of the bridge chip component, wherein the top redistribution layer comprises a dielectric layer and an electroplated wire located within the dielectric layer, wherein the electroplated wire is electrically connected to the bridge chip component, and wherein the electroplated wire is formed using an electroplating process;
forming a top pad on a top surface of the top redistribution layer, wherein the top pad is electrically connected to the top redistribution layer;
arranging a top device on the top redistribution layer, wherein the top device is soldered with the top pad; and
molding to form a second molding layer, wherein the second molding layer covers the top device.

11. The method for forming a package structure according to claim 1, wherein forming a bottom redistribution layer on the bottom surface of the first molding layer and the bottom surface of the bridge chip component comprises:
forming a dielectric layer on the bottom surface of the first molding layer and the bottom surface of the bridge chip component;
forming, on the dielectric layer, a through-via exposing the bottom surface of the through-silicon-via or a bottom pad of the bottom surface of the through-silicon-via through a single exposure or a double exposure process; and
forming an electroplated bump within the through-via to by at least one of sputtering and electroplating methods, wherein the electroplated bump is in contact with the through-silicon-via or the bottom pad.

12. The method for forming a package structure according to claim 1, wherein after forming a bottom redistribution layer on the bottom surface of the first molding layer and the bottom surface of the bridge chip component, the method further comprises:
forming a conductive connection structure on a bottom surface of the bottom redistribution layer.

13. A package structure, comprising:
a bridge chip component, wherein:
the bridge chip component comprises a bridge chip and a protective layer;
the bridge chip comprises a base body and a through-silicon-via extending through the base body; and
the protective layer is arranged on a bottom surface of the base body and exposes a bottom surface of the through-silicon-via, wherein the bottom surface of the through-silicon-via is flush with a bottom surface of the protective layer;
a first molding layer, wherein the first molding layer covers a side surface of the bridge chip component, and a bottom surface of the bridge chip component is higher than a bottom surface of the first molding layer;
a chip package component arranged on a top surface of the first molding layer and a top surface of the bridge chip component, wherein the bridge chip component is electrically connected to the chip package component; and
a bottom redistribution layer arranged on the bottom surface of the first molding layer and the bottom surface of the bridge chip component, wherein a thickness of the bottom redistribution layer located on the bottom surface of the bridge chip component is greater than that of the bottom redistribution layer located on the bottom surface of the first molding layer, and the bridge chip component is electrically connected to the bottom redistribution layer.

14. The package structure according to claim 13, wherein the bridge chip component further comprises a bottom pad, wherein the bottom pad is arranged on the bottom surface of the through-silicon-via and electrically connected to the through-silicon-via, and the bottom redistribution layer is electrically connected to the bottom pad.

15. The package structure according to claim 14, wherein the bridge chip component further comprises a seed layer arranged between the bottom pad and the bottom surface of the through-silicon-via.

16. The package structure according to claim 13, further comprising:
a passivation layer arranged on a side surface of the through-silicon-via;
a metal pillar, wherein the metal pillar extends through the first molding layer, and a bottom surface of the metal pillar is flush with the bottom surface of the first molding layer; and
a conductive connection structure, wherein the conductive connection structure is arranged on a bottom surface of the bottom redistribution layer.

17. The package structure according to claim 13, wherein the bridge chip component further comprises:
an internal redistribution layer arranged on a top surface of the base body and electrically connected to a top surface of the through-silicon-via; and
a conductive pillar arranged on a top surface of the internal redistribution layer and electrically connected to the internal redistribution layer, wherein the chip package component is electrically connected to the conductive pillar.

18. The package structure according to claim 13, wherein the bridge chip further comprises a deep trench capacitor, and the deep trench capacitor is arranged within the base body.

19. The package structure according to claim 14, wherein the bottom redistribution layer comprises a dielectric layer and an electroplated bump located within the dielectric layer, and the electroplated bump is in contact with the bottom surface of the through-silicon-via or a bottom surface of the bottom pad.

20. The package structure according to claim 13, wherein the chip package component comprises:
a top redistribution layer arranged on a top surface of the first molding layer and the top surface of the bridge chip component, wherein the top redistribution layer comprises a dielectric layer and an electroplated wire within the dielectric layer, and the electroplated wire is electrically connected to the bridge chip component;
a top pad arranged on the top redistribution layer and electrically connected to the top redistribution layer;
a top device arranged on the top redistribution layer, wherein the top device is soldered to the top pad; and
a second molding layer covering the top device.
